(19) United States
(12) Patent Application Publication
(10) Pub. No.: US 2002/0104047 A1
(43) Pub. Date: Aug. 1, 2002

(54) Financial document processing system and method of operating a financial document processing system

(75) Inventor: Joseph Cosentino, Hamilton (CA)

Correspondence Address: Intellectual Property Section, Law Department, NCR Corporation, 101 West Schantz, ECD-2, Dayton, OH, 45479-0001, US

(73) Assignee: NCR Corporation, Dayton, OH (US)

(21) Appl. No.: 09/774,992

(22) Filed: Jan. 31, 2001

(51) Int. Cl. H03K 19/003

(52) U.S. Cl. 714/47

(57) ABSTRACT

A method of operating a financial document processing system comprises the steps of (a) monitoring a number of operating parameters associated with operation of the system, (b) storing a number of operating parameters of step (a) into a database, and (c) processing at least some of the parameters stored in the database to provide a number of signals indicative of a potential fault condition.

### BACKGROUND OF THE INVENTION

The present invention relates to financial document processing systems, and is particularly directed to image-based check processing systems.

A typical image-based check processing system includes a check processing transport which has a document transport path and a number of different hardware devices positioned along the document transport path for performing specific document processing operations on documents moving downstream along the document transport path. The check processing system also includes a transport processor which executes a transport application program which is stored in memory to control operation of the devices positioned along the document transport path and thereby to control operation of the check processing transport.

From time to time, a fault condition may occur while processing documents on the check processing transport. Fault conditions include document jams, hardware failures, application errors, media low or empty, a pocket full, for examples. Typically, when a fault condition occurs, any document in the document transport path that has not been completely processed is manually located by an operator and removed from the document transport path. To avoid problems further downstream, the operator must ensure that all documents which have not been completely processed are removed from the document transport path. Once the problem that caused the fault condition is resolved, the operator must reprocess the documents in their original order.

When a fault condition occurs, much valuable operator time may be required to correct the problem that caused the fault condition, as well as to restore documents to their order and position just right before occurrence of the fault condition. Since much operator time may be required, there is usually a relatively high cost when a fault condition occurs. Accordingly, it would be desirable to minimize occurrence of fault conditions in an image-based check processing system.

### SUMMARY OF THE INVENTION

In accordance with one aspect of the present invention, a method of operating a financial document processing system comprises the steps of (a) monitoring a number of operating parameters associated with operation of the system, (b) storing a number of operating parameters of step (a) into a database, and (c) processing at least some of the parameters stored in the database to provide a number of signals indicative of a potential fault condition.

A message may displayed to assist an operator in diagnosing the potential fault condition before the potential fault condition actually occurs. A number of actions may be displayed on a screen to assist the operator in diagnosing the potential fault condition. As an example, specific instructions may be displayed to provide a step-by-step approach to diagnosing the potential fault condition. As another example, a determination may be made periodically to determine if the signals indicative of the potential fault condition match a predetermined fault pattern. An operator may be alerted when the signals indicative of the potential fault condition match the predetermined fault pattern. Moreover, a fault event may be logged when the signals indicative of the potential fault condition match the predetermined fault pattern.

In accordance with another aspect of the present invention, a financial document processing system comprises means for monitoring a number of operating parameters associated with operation of the system, means for storing a number of operating parameters into a database, and means for processing at least some of the parameters stored in the database to provide a number of signals indicative of a potential fault condition.

In accordance with still another aspect of the present invention, a program storage medium is readable by a computer having a memory. The medium tangibly embodies one or more programs of instructions executable by the computer to perform method steps for operating a financial document processing system. The method comprises the steps of (a) monitoring a number of operating parameters associated with operation of the system, (b) storing a number of operating parameters of step (a) into a database, and (c) processing at least some of the parameters stored in the database to provide a number of signals indicative of a potential fault condition.

### BRIEF DESCRIPTION OF THE DRAWINGS

The foregoing and other features of the present invention will become apparent to one skilled in the art to which the present invention relates upon consideration of the following description of the invention with reference to the accompanying drawings, wherein:

FIG. 1 is a schematic block representation of an image-based check processing system embodying the present invention;

FIG. 2 is a schematic block representation of a portion of FIG. 1; and

FIGS. 3, 4, 5, and 6 are flowcharts depicting processes carried out in accordance with the present invention.

### DETAILS OF THE INVENTION

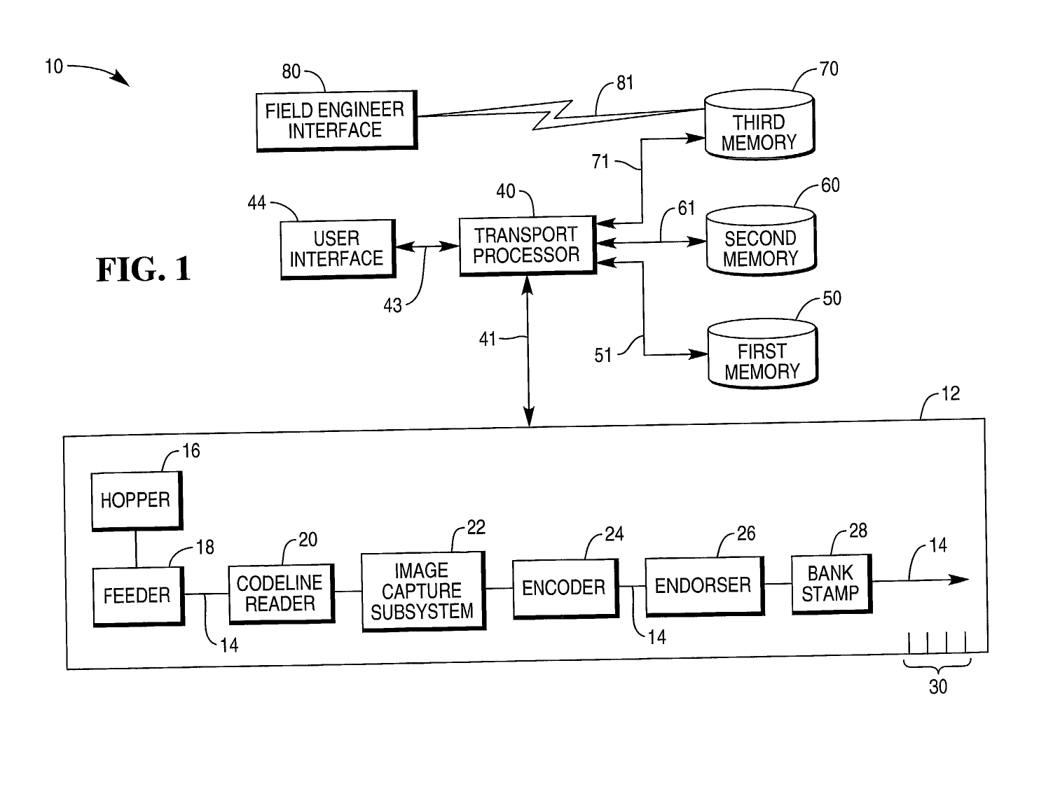

The present invention is directed to financial document processing systems and a method of operating a financial document processing system. The specific construction and use of the financial document processing system may vary. By way of example, a financial document processing system in the form of an image-based check processing system 10 is illustrated in FIG. 1. The check processing system 10 may be, for example, a sorting machine or a proof machine wherein financial documents such as checks are processed in a bank.

As shown in FIG. 1, the check processing system 10 includes a check processing transport 12 having a document track which defines a document transport path 14 along which financial documents, such as checks, can be transported from an upstream end to a downstream end. The transport 12 includes a number of different hardware devices lying along the document transport path 14 for performing specific document processing operations on documents moving along the document transport path 14. The transport 12 includes a document hopper 16 into which a stack of financial documents including checks are placed. A document feeder 18 adjacent the hopper 16 selectively feeds or drives each document from the stack of documents in the hopper to transport the document from the upstream end to the downstream end along the document transport path 14 to sorting bins 30 located at the end of the document transport path.

The check processing system 10 further includes a codeline reader 20 such as a MICR reader located along the document transport path 14. The MICR reader 20 reads a MICR codeline from each check being processed in a known manner. Alternatively, the codeline reader may be an OCR reader instead of a MICR reader depending upon on the particular application.

The check processing system 10 further includes an image capture subsystem 22 located along the document transport path 14. The image capture subsystem 22 captures an image of each document for a number of different purposes well known in the financial industry. More specifically, the image capture subsystem 22 includes an imaging camera (not shown) which is controlled to capture images of documents moving along the document transport path 14.

An encoder 24 encodes missing fields on each check. An endorser 26 applies an endorsement in a known manner to each check. A bank stamp 28 stamps each check to identify the bank institution processing the check. The structure and operation of MICR readers, OCR readers, imaging cameras, encoders, endorsers, and bank stamps are well known and, therefore, will not be described.

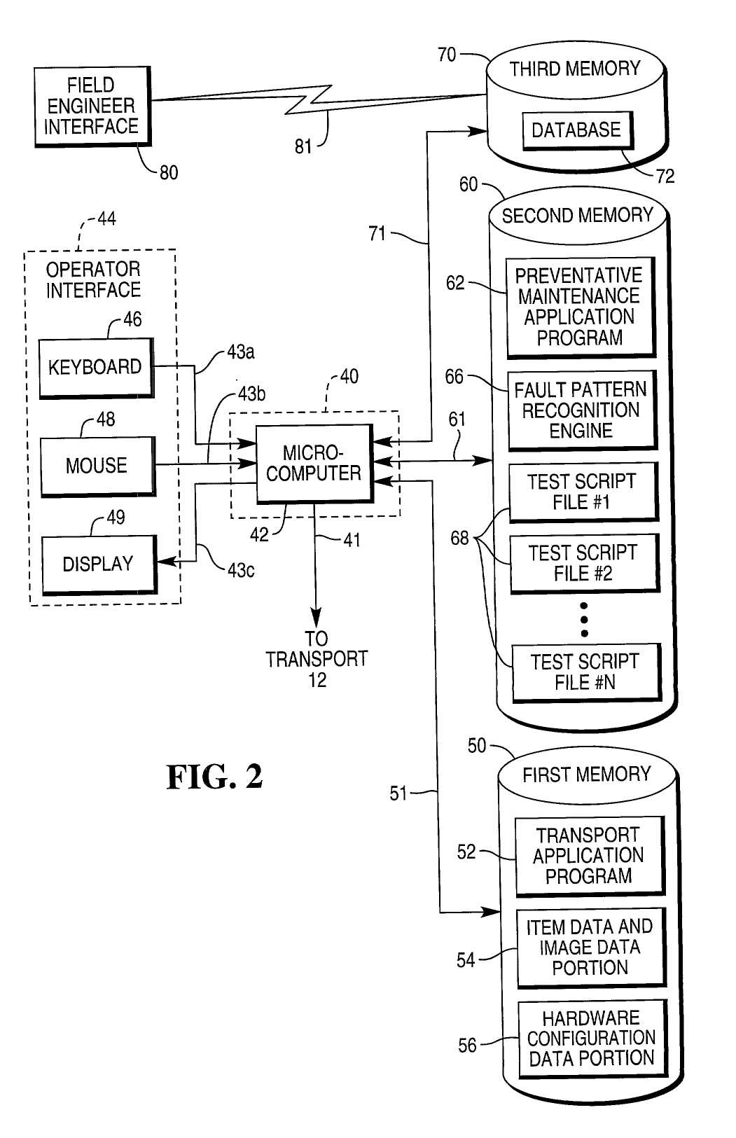

Referring to FIGS. 1 and 2, the check processing system 10 further includes a transport processor 40 and an operator interface 44 which communicates via signals on line 43 (FIG. 1) with a microcomputer 42 of the transport processor 40. The operator interface 44 includes a keyboard 46, a mouse 48, and a display 49, all of which communicate via signals on lines 43a, 43b, 43c (FIG. 2) with the microcomputer 42. The microcomputer 42 controls operation of the transport 12 via signals on line 41. Suitable microcomputers and memories are readily available in the marketplace. Their structure and operation are well known and, therefore, will not be described.

The check processing system 10 also includes a first memory 50 which communicates via signals on line 51 with the microcomputer 42. It is contemplated that the first memory 50 could be a single memory unit or a plurality of different memory units. An executable transport application program 52 is stored in the first memory 50. The transport application program 52 is associated with a particular type of document processing work. For example, one type of work is proof of deposit. Another type of work is remittance processing. Still another type of work may be sorting of items. When the transport application program 52 is executed, the hardware devices lying along the document transport path 14 are controlled to process items moving downstream along the document transport path in accordance with the transport application program, as is known.

The first memory 50 includes an item data and image data portion 54 which stores sequence numbers, MICR codelines, image data, encoder status, endorsement status, and bank stamp status associated with transaction items which have been processed in accordance with the transport application program 52. The first memory 50 further includes a hardware configuration data portion 56 which stores configuration data specific to each of the hardware devices lying along the document transport path 14.

The check processing system 10 further includes a second memory 60 which communicates on line 61 with the microcomputer 42. A preventive maintenance application program 62 is stored in the second memory 60. The second memory 60 also stores a fault recognition engine 66 and a number of script files 68 in accordance with the present invention to be described in more detail hereinbelow.

The check processing system 10 also includes a third memory 70 which communicates on line 71 with the microcomputer 42. The third memory 70 also communicates via a wireless connection 81 with a field engineer interface 80 which is located remote from the third memory. In particular, the third memory 70 includes a preventive maintenance database 72 which stores preventive maintenance information from operation of the check processing system 10. More specifically, the database 72 stores data relating to certain items during operation of the image-based check processing system 10. The data stored in the database 72 represents the current state of output operations (i.e., all completed and incomplete output operations) for each item which may become involved in a fault condition along the document transport path 14.

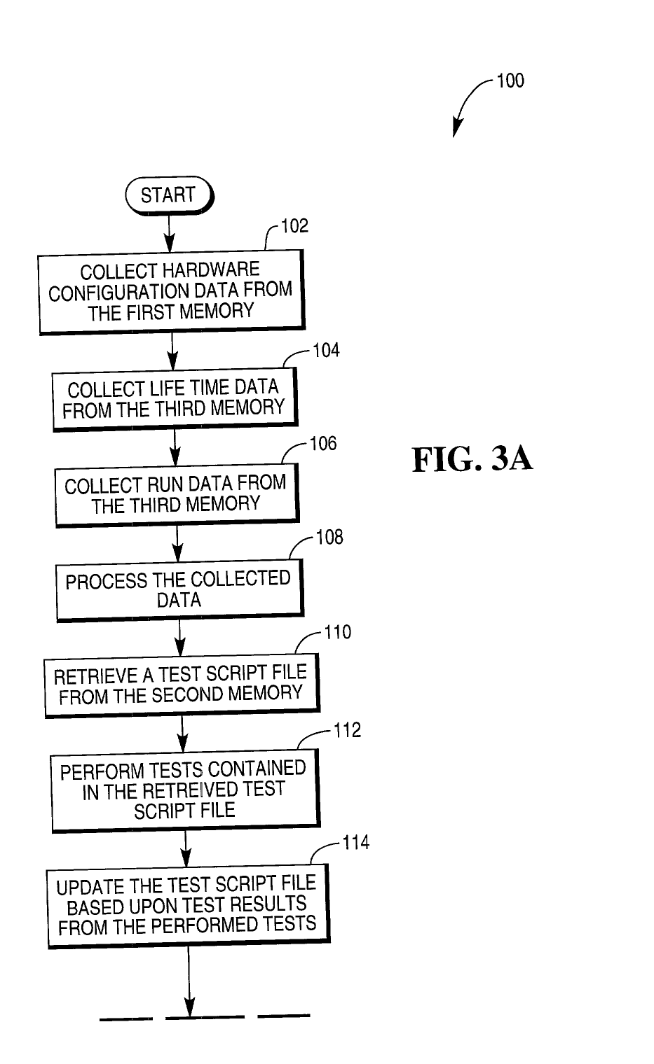

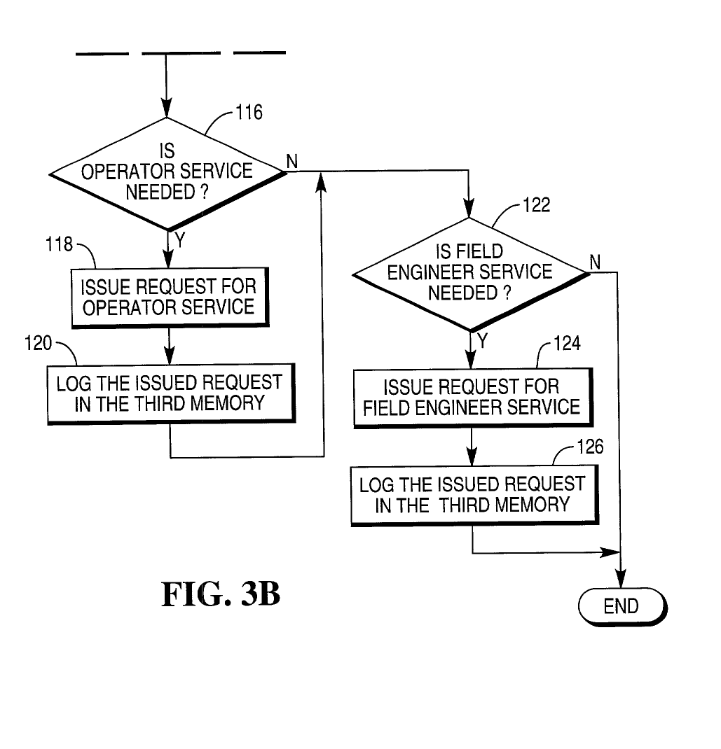

When a fault condition, such as a document jam for example, occurs along the document transport path 14, a fault condition recovery process is initiated. FIG. 3 is an overview flowchart 100 which depicts operation of the prevention maintenance application program 62 which is initiated during operation of the image-based check processing system 10. In step 102, hardware configuration data including data associated with the hardware devices lying along the document transport path 14 is obtained from the first memory 50. Similarly, as shown in step 104, life time data is obtained from the third memory 70. Also, as shown in step 106, run data is obtained from the third memory 70. Then, in step 108, the data collected in steps 102, 104, and 106 is processed.

The process then proceeds to step 110 in which one of the test script files 68 is obtained from the second memory 60. As shown in step 112, the tests contained in the retrieved test script file are performed. After the tests have been performed, that particular test script file is updated based upon test results from the tests which have just been performed. By updating each test script file in this manner, the tests contained in the test script file may adjust themselves for the nature of work at a particular site. Data from a number of sites may be collected to construct improved fault finding test script files.

The process proceeds to step 116 in which the fault pattern recognition engine 66 makes a determination as to whether any operator service is needed based upon the test results from the tests which were performed in step 112. If the determination in step 118 is affirmative, the process proceeds to step 118 in which a request for operator service is issued. The issued request for operator service is logged in the third memory 70, as shown in step 120, before the process proceeds to step 122. However, if the determination in step 116 is negative, the process proceeds directly to step 122.

In step 122, the fault pattern recognition engine 66 makes a determination as to whether any field engineer service is needed based upon the test results from the tests which were performed in step 112. If the determination in step 122 is negative, then the process ends. However, if the determination in step 122 is affirmative, the process proceeds to step 124 in which a request for field engineer service is issued. The issued request for field engineer service is logged in the third memory 70, as shown in step 126, before the process ends.

It is contemplated that the fault pattern recognition engine 66 could be based upon a neural network which could be trained by collecting a large body of data from numerous databases. In this case, data would need to be conditioned into a useful input vector for neural network training. The trained neural network could then be used in place of or in addition to the test script files 68 to help diagnose problems.

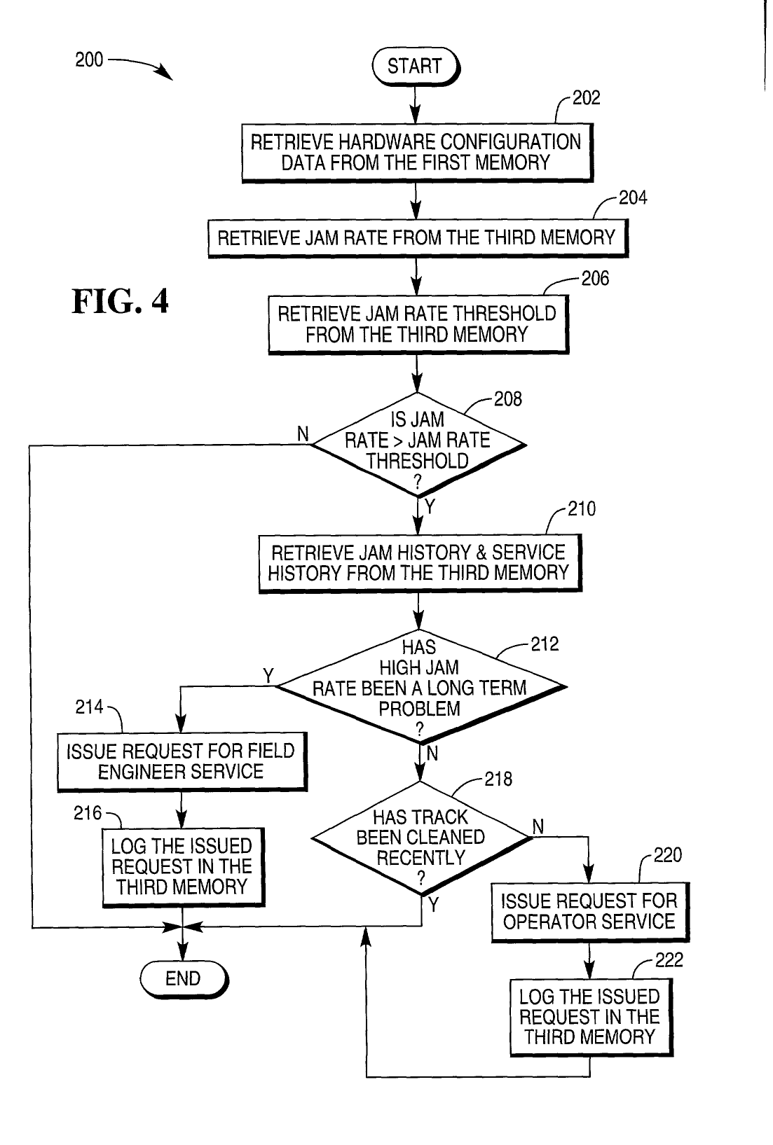

FIG. 4 is a detailed flowchart 200 which depicts operation of a first preventive maintenance process including operation of the preventive maintenance program 62 in accordance with the present invention. The first preventive maintenance process operates to prevent occurrence of document jams along the document transport path 14. In step 202, hardware configuration data including data associated with the hardware devices lying along the document transport path 14 is obtained from the first memory 50. As shown in step 204, data corresponding to jam rate along the document transport path 14 is obtained from the third memory 70. Also, as shown in step 206, data corresponding to a jam rate threshold is obtained from the third memory 70.

In step 208, a determination is made as to whether the jam rate of step 204 is greater than the jam rate threshold of step 206. If the determination in step 208 is affirmative, the process proceeds to step 210 in which the jam history and the service history are obtained from the third memory 70 for examination. The process proceeds to step 212 in which a determination is made as to whether a high jam rate has been a long term problem. This determination is based upon the jam history and the service history which were retrieved from the third memory 70 in step 210. If the determination in step 212 is affirmative, the process proceeds to step 214 in which a request for field engineer service is issued. The issued request for field engineer service is logged in the third memory 70, as shown in step 216, before the process ends.

However, if the determination in step 212 is negative, the process proceeds to step 218 in which a determination is made as to whether the track of the document transport path 14 has been cleaned recently. This determination is based upon the jam history and the service history which were retrieved from the third memory 70 in step 210. If the determination in step 218 is affirmative, the process ends. If the determination in step 218 is negative, the process proceeds to step 220 in which a request for operator service is issued. The issued request for operator service is logged in the third memory 70, as shown in step 222, before the process ends.

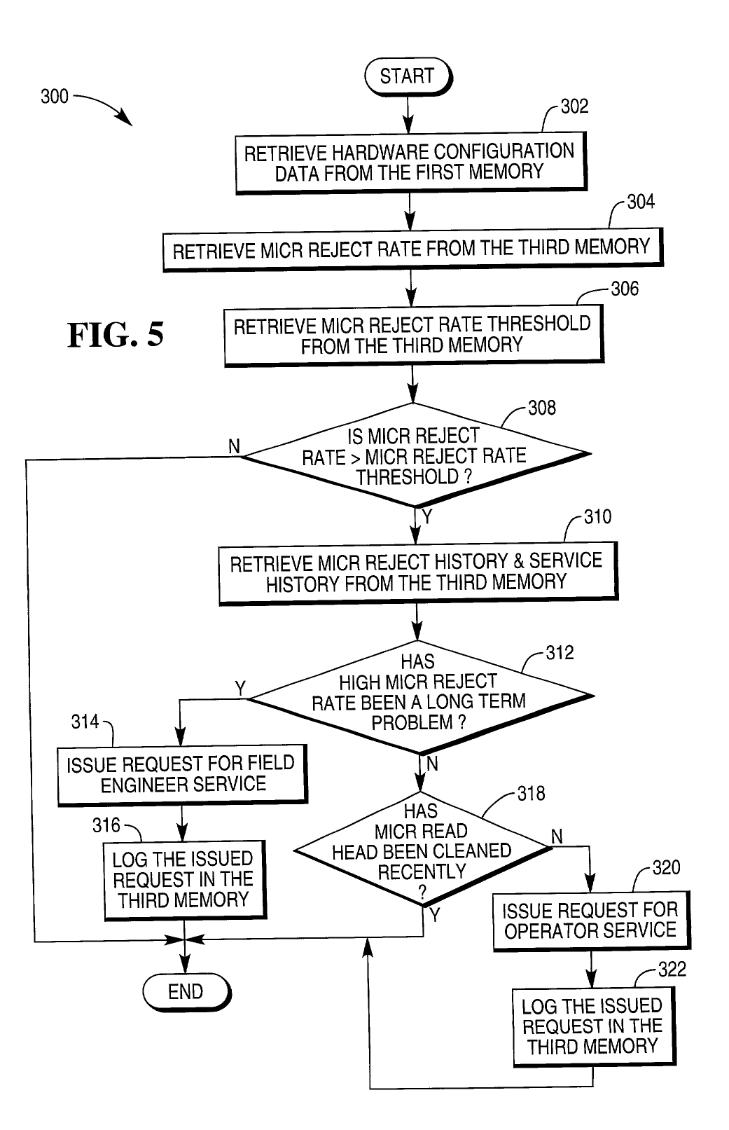

FIG. 5 is a detailed flowchart 300 which depicts operation of a second preventive maintenance process including operation of the preventive maintenance program 62 in accordance with the present invention. The second preventive maintenance process operates to prevent occurrence of MICR rejects during operation of the check processing system 10. In step 302, hardware configuration data including data associated with the hardware devices lying along the document transport path 14 is obtained from the first memory 50. As shown in step 304, data corresponding to MICR reject rate is obtained from the third memory 70. Also, as shown in step 306, data corresponding to a MICR reject rate threshold is obtained from the third memory 70.

In step 308, a determination is made as to whether the MICR reject rate of step 304 is greater than the MICR reject rate threshold of step 306. If the determination in step 308 is affirmative, the process proceeds to step 310 in which the MICR reject history and the service history are obtained from the third memory 70 for examination. The process proceeds to step 312 in which a determination is made as to whether a high MICR reject rate has been a long term problem. This determination is based upon the MICR reject history and the service history which were retrieved from the third memory 70 in step 310. If the determination in step 312 is affirmative, the process proceeds to step 314 in which a request for field engineer service is issued. The issued request for field engineer service is logged in the third memory 70, as shown in step 216, before the process ends.

However, if the determination in step 312 is negative, the process proceeds to step 318 in which a determination is made as to whether the MICR read head has been cleaned recently. This determination is based upon the MICR reject history and the service history which were retrieved from the third memory 70 in step 310. If the determination in step 318 is affirmative, the process ends. However, if the determination in step 318 is negative, the process proceeds to step 320 in which a request for operator service is issued. The issued request for operator service is logged in the third memory 70, as shown in step 322, before the process ends.

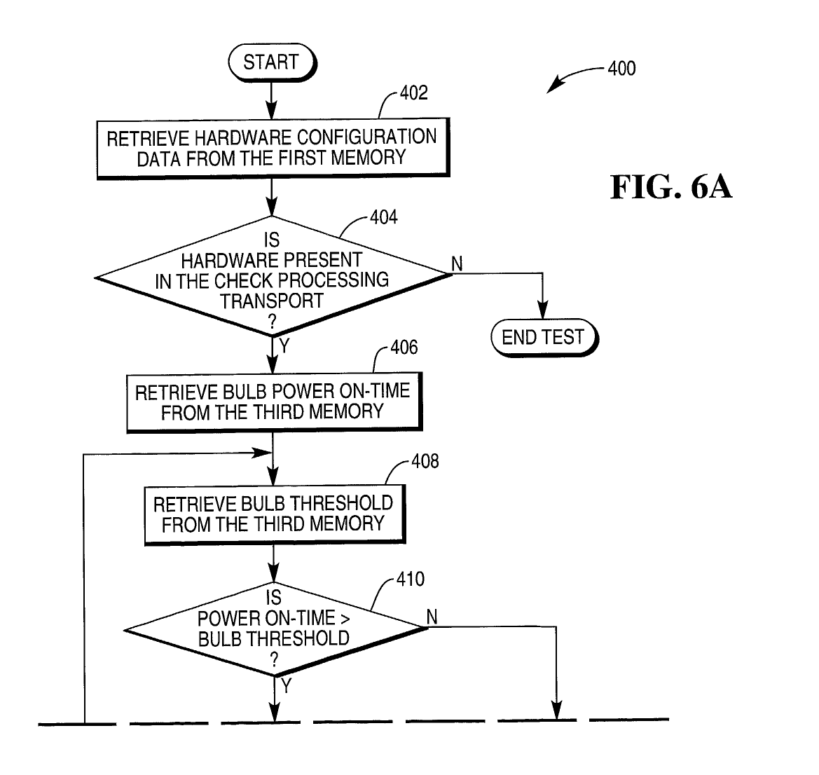

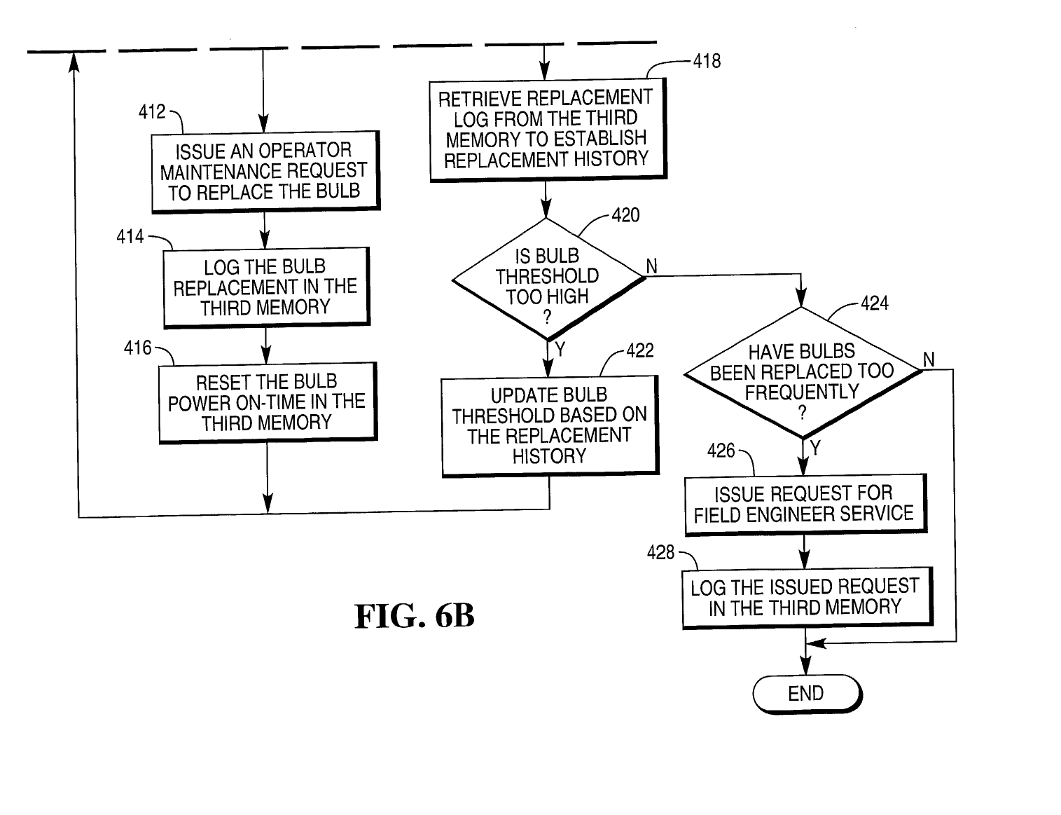

FIG. 6 is a detailed flowchart 400 which depicts operation of a third preventive maintenance process including operation of the preventive maintenance program 62 in accordance with the present invention. The third preventive maintenance process operates to reduce downtime resulting from bulb failure during operation of the check processing system 10. In step 402, hardware configuration data including data associated with the hardware devices lying along the document transport path 14 is obtained from the first memory 50. A determination is made in step 404 as to whether any hardware is present in the check processing transport 12. If the determination in step 404 is negative, the process ends. However, if the determination in step 404 is affirmative, the process proceeds to step 406.

In step 406, data corresponding to bulb power-on time is retrieved from the third memory 70. Also, as shown in step 408, data corresponding to a bulb threshold is obtained from the third memory 70. In step 410, a determination is made as to whether the power on-time of step 406 is greater than the bulb threshold of step 408. If the determination in step 410 is affirmative, the process proceeds to step 412 in which an operator maintenance request to replace the bulb is issued. The issued request is logged in the third memory 70, as shown in step 414. The process then proceeds to step 416 in which the bulb power-on time stored in the third memory 70 is reset before returning to step 408 to repeat steps starting from step 408.

However, if the determination in step 410 is negative, the process proceeds to step 418 in which a replacement log is retrieved from the third memory 70 to establish a replacement history. A determination is then made in step 420 as to whether the bulb threshold of step 408 is too high. This determination is based upon the contained in the replacement log of step 418. If the determination in step 420 is affirmative, the process proceeds to step 422 in which the bulb threshold is updated based upon the replacement history of step 418 before returning to step 408 to repeat steps starting from step 408. If the determination in step 420 is negative, the process proceeds to step 424.

In step 424, a determination is made as to whether bulbs have been replaced too frequently. This determination is based upon data contained in the replacement history of step 418. If the determination in step 424 is negative, the process ends. However, if the determination in step 424 is affirmative, the process proceeds to step 426 in which a request for field engineer service is issued since a more serious problem, such as a fan or power problem, may be present. The issued request for field engineer service is logged in the third memory 70, as shown in step 428, before the process ends servicing of a potential problem is altered.

It should be apparent that fault patterns are recognized as hardware ages and regular maintenance is performed over the life of the check processing system 10. A number of advantages result by recognizing fault patterns in accordance with the present invention. One advantage is that a potential fault condition is displayed on the display 49 to assist an operator in performing preventive maintenance on the check processing system 10 before the fault condition actually occurs. The operator is assisted by leading the operator through to diagnose the potential condition before an actual fault condition actually occurs in the check processing system 10. The result is a reduced number of actual fault conditions. In addition, the severity of actual fault conditions may be reduced. Accordingly, a relatively inexperienced operator is better able to handle actual fault conditions without assistance. This results in higher productivity of operators. Also, less training of operators is needed. Another advantage is that the number of service calls and downtime of the check processing system 10 is reduced.

It is contemplated that the above-described programs be available on portable storage media, such as a compact disc read only memory (CDROM)). The programs on a CDROM may be installed on different financial document processing systems to provide these systems with corresponding capabilities as described above. It is also contemplated that the potential fault identification process described above may be used in other types of financial document processing systems, such as non-image-based systems, for example.

From the above description of the invention, those skilled in the art to which the present invention relates will perceive improvements, changes and modifications. Numerous substitutions and modifications can be undertaken without departing from the true spirit and scope of the invention. Such improvements, changes and modifications within the skill of the art to which the present invention relates are intended to be covered by the appended claims.

What is claimed is:

1. A method of operating a financial document processing system, the method comprising the steps of:
(a) monitoring a number of operating parameters associated with operation of the system;
(b) storing a number of operating parameters of step (a) into a database; and
(c) processing at least some of the parameters stored in the database to provide a number of signals indicative of a potential fault condition.

2. A method according to claim 1, further comprising the step of:
(d) displaying a message to assist an operator in diagnosing the potential fault condition before the potential fault condition actually occurs.

3. A method according to claim 1, further comprising the step of:
(d) periodically determining if the signals indicative of the potential fault condition match a predetermined fault pattern.

4. A method according to claim 3, further comprising the step of:
(e) alerting an operator when the signals indicative of the potential fault condition match the predetermined fault pattern.

5. A method according to claim 3, further comprising the step of:
(e) logging a fault event when the signals indicative of the potential fault condition match the predetermined fault pattern.

6. A method according to claim 1, further comprising the step of:
(d) displaying a number of actions on a screen to assist the operator in diagnosing the potential fault condition.

7. A method according to claim 6, wherein step (d) includes the step of:
(d-1) displaying specific instructions to provide a step-by-step approach to diagnosing the potential fault condition.

8. A financial document processing system comprising:
means for monitoring a number of operating parameters associated with operation of the system;
means for storing a number of operating parameters into a database; and
means for processing at least some of the parameters stored in the database to provide a number of signals indicative of a potential fault condition.

9. A financial document processing system according to claim 8, further comprising means for displaying a message to assist an operator in diagnosing the potential fault condition before the potential fault condition actually occurs.

10. A financial document processing system according to claim 8, further comprising means for periodically determining if the signals indicative of the potential fault condition match a predetermined fault pattern.

11. A financial document processing system according to claim 10, further comprising means for alerting an operator when the signals indicative of the potential fault condition match the predetermined fault pattern.

12. A financial document processing system according to claim 10, further comprising means for logging a fault event when the signals indicative of the potential fault condition match the predetermined fault pattern.

13. A financial document processing system according to claim 8, further comprising means for displaying a number of actions on a screen to assist the operator in diagnosing the potential fault condition.

14. A financial document processing system according to claim 13, wherein the displaying means includes means for displaying specific instructions to provide a step-by-step approach to diagnosing the potential fault condition.

15. A program storage medium readable by a computer having a memory, the medium tangibly embodying one or more programs of instructions executable by the computer to perform method steps for operating a financial document processing system, the method comprising the steps of:
(a) monitoring a number of operating parameters associated with operation of the system;
(b) storing a number of operating parameters of step (a) into a database; and
(c) processing at least some of the parameters stored in the database to provide a number of signals indicative of a potential fault condition.

16. A program storage medium according to claim 15, wherein the method further comprises the step of:
(d) displaying a message to assist an operator in diagnosing the potential fault condition before the potential fault condition actually occurs.

17. A program storage medium according to claim 15, wherein the method further comprises the step of:
(d) periodically determining if the signals indicative of the potential fault condition match a predetermined fault pattern.

18. A program storage medium according to claim 17, wherein the method further comprises the step of:
(e) alerting an operator when the signals indicative of the potential fault condition match the predetermined fault pattern.

19. A program storage medium according to claim 17, wherein the method further comprises the step of:
(e) logging a fault event when the signals indicative of the potential fault condition match the predetermined fault pattern.

20. A program storage medium according to claim 15, wherein the method further comprises the step of:
(d) displaying a number of actions on a screen to assist the operator in diagnosing the potential fault condition.

21. A program storage medium according to claim 20, wherein the method further comprises the step of:
(d-1) displaying specific instructions to provide a step-by-step approach to diagnosing the potential fault condition.
